(19) United States
(12) Patent Application Publication
(10) Pub. No.: US 2015/0122328 A1
(43) Pub. Date: May 7, 2015

(54) SOLAR CELL AND SOLAR CELL MODULE INCLUDING THE SAME

(71) Applicant: Electronics and Telecommunications Research Institute, Daejeon (KR)

(72) Inventors: Jungwook LIM, Daejeon (KR); Kyu Sung LEE, Daejeon (KR); Sun Jin YUN, Daejeon (KR)

(73) Assignee: Electronics and Telecommunications Research Institute, Daejeon (KR)

(21) Appl. No.: 14/336,551

(22) Filed: Jul. 21, 2014

(30) Foreign Application Priority Data
Nov. 7, 2013 (KR) 10-2013-0134938
Jan. 23, 2014 (KR) 10-2014-0008473

(51) Int. Cl. H01L 31/055; H01L 31/054; H01L 31/0352

(52) U.S. Cl. CPC H01L 31/055; H01L 31/035218; H01L 31/0543
USPC 136/257

(57) ABSTRACT

Provided are solar cell and a solar cell module including the same. The solar cell includes a first light conversion layer, a lower electrode layer disposed on the first light conversion layer, a light absorption layer disposed on the lower electrode layer to absorb solar light, and an upper electrode layer disposed on the light absorption layer. Here, the first light conversion layer includes a lower refraction layer through which the solar light is transmitted and first light conversion particles absorbing refracted light, in which the solar light is refracted by the lower refraction layer, to generate first emission light.

### CROSS-REFERENCE TO RELATED APPLICATIONS

This U.S. non-provisional patent application claims priority under 35 U.S.C. §119 of Korean Patent Application Nos. 10-2013-0134938, filed on Nov. 7, 2013, and 10-2014-0008473, filed on Jan. 23, 2014, the entire contents of which are hereby incorporated by reference.

### BACKGROUND OF THE INVENTION

The present invention disclosed herein relates to a solar cell and a solar cell module including the same, and more particularly, to a solar cell using a luminescent solar concentrator and a solar cell module including the same.

In recent, building-integrated photovoltaics (BIPV) are being developed in photovoltaic fields such roofs of houses or tiles of buildings. However, if photovoltaic (PV) windows that are applied to windows of buildings or houses are mass-produced in earnest, large markets are expected to be generated. In case of dye-sensitized solar cells or organic solar cells, it may be difficult to secure stability that is significantly deteriorated in large area, the dye-sensitized solar cells or organic solar cells have difficulty in application of large-area windows. Also, in case of thin-film solar cells, it may be difficult to secure sufficient visibility and realize color and transmittance.

One of these technologies that are suitable for the PV windows is to use a phosphor. The phosphor may absorb solar light that is not absorbed into the solar cell to provide the emission light of a visible light region to the solar cell. In general, the phosphor may be disposed at an upper portion of the solar cell. The solar cell may absorb the solar light and the emission light to generate power.

However, the general solar cell may absorb emission light that is provided from an upper side thereof. Thus, the general solar cell may very restrictively increase in light absorption efficiency.

### SUMMARY OF THE INVENTION

The present invention provides a solar cell that is capable of maximizing light absorption efficiency and a solar cell module including the same.

Embodiments of the present invention provide solar cells including: a first light conversion layer; a lower electrode layer disposed on the first light conversion layer; a light absorption layer disposed on the lower electrode layer to absorb solar light; and an upper electrode layer disposed on the light absorption layer, wherein the first light conversion layer includes: a lower refraction layer through which the solar light is transmitted; and first light conversion particles absorbing refracted light, in which the solar light is refracted by the lower refraction layer, to generate first emission light.

In some embodiments, the first light conversion particles may include phosphors.

In other embodiments, the phosphors may include lanthanum-based metal particles.

In still other embodiments, the solar cell may absorb the solar light of a visible light region and transmit the solar light of an infrared light region having a wavelength longer than that of the visible light region, and the first light conversion particles may absorb the solar light of the infrared light region to provide the first emission light of the visible light region to the light absorption layer.

In even other embodiments, the solar cells may further include a second light conversion layer disposed on the upper electrode layer.

In yet other embodiments, the second light conversion layer may include: an upper refraction layer through which the solar light is transmitted; and second light conversion particles disposed within the upper refraction layer to absorb the solar light of an ultraviolet light region having a wavelength less than that of the visible light region, thereby generating second emission light of the visible light region.

In further embodiments, the second light conversion particles may include quantum dots.

In still further embodiments, the quantum dots may include cadmium sulfide (CdS).

In even further embodiments, each of the lower refraction layer and the upper refraction layer may include aluminum oxide (Al₂O₃), titanium oxide (TiO₂), or vanadium oxide (V₂O₃).

In other embodiments of the present invention, solar cell modules include: a refraction plate; first light conversion particles disposed within the refraction plate to absorb solar light that is refracted by the refraction plate, thereby generating first emission light; and a solar cell disposed on the refraction plate to absorb the solar light and the first emission light, thereby generating power.

In some embodiments, the first light conversion particles may include luminescent solar concentrators.

In other embodiments, the luminescent solar concentrators may include phosphors.

In still other embodiments, the phosphors may include lanthanum-based metal particles.

In even other embodiments, the refraction plate may include polymethylmethacrylate (PMMA) or polydimethylsiloxane (PDMS).

In yet other embodiments, the first light conversion particles may absorb the solar light of an infrared light region.

In further embodiments, the solar cell may include: a lower electrode layer disposed on the light conversion plate; a light absorption layer disposed on the lower electrode layer; an upper electrode layer disposed on the light absorption layer; and a light conversion layer disposed on the upper electrode layer to absorb the solar light, thereby generating second emission light, wherein light absorption layer may transmit the solar light of the infrared light region to absorb the solar light of a visible light region having a wavelength less than that of the infrared light region, the first emission light, and the second emission light.

In still further embodiments, the second light conversion layer may include: a refraction layer disposed on the upper electrode layer; and second light conversion particles disposed within the refraction layer.

In even further embodiments, the second light conversion particles may include quantum dots.

In yet further embodiments, the solar cell modules may further include refractive index gradient plates disposed under the light conversion plate, each refractive index gradient plate having a refractive index less than that of the first light conversion plate.

In much further embodiments, the refractive index gradient plates may include: a first refractive index gradient plate disposed under the light conversion plate; and a second refractive index gradient plate disposed under the first refractive index gradient plate, the second refractive index gradient plate having a refractive index less than that of the first refractive index gradient plate.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a perspective view of a solar cell module according to an embodiment of the present invention;

FIG. 2 is a cross-sectional view of the solar cell of FIG. 1;

FIG. 3 is a perspective view of a solar cell module according to another embodiment of the present invention; and

FIG. 4 is a cross-sectional view of a solar cell according to an application example of the present invention.

### DETAILED DESCRIPTION OF PREFERRED EMBODIMENTS

Preferred embodiments of the present invention will be described below in detail with reference to the accompanying drawings. Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Like reference numerals refer to like elements throughout.

In the following description, the technical terms are used only for explaining a specific exemplary embodiment while not limiting the present invention.

The meaning of ‘comprises’ and/or ‘comprising’ specifies a component, a step, an operation and/or an element does not exclude other components, steps, operations and/or elements. Since preferred embodiments are provided below, the order of the reference numerals given in the description is not limited thereto.

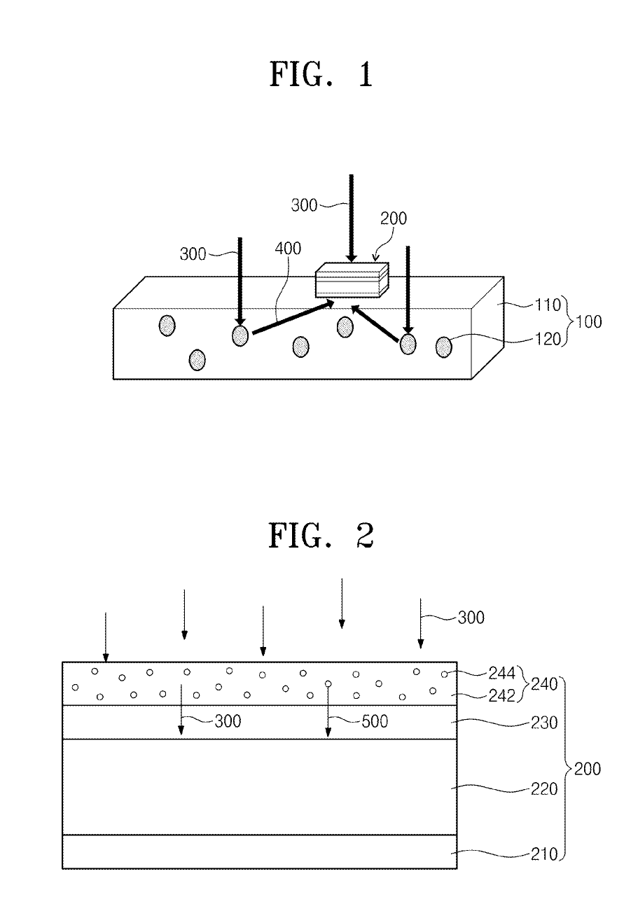

FIG. 1 is a perspective view of a solar cell module according to the present invention.

Referring to FIG. 1, a solar cell module according to an embodiment of the present invention may include a light conversion plate 100 and a solar cell 200.

The light conversion plate 100 may refract solar light 300 of a visible light region. The solar light 300 of the visible light region may have a wavelength less than that of solar light of an infrared light region. The light conversion plate 100 may absorb the solar light 300 of the infrared and ultraviolet (UV) light regions. The light conversion plate 100 may generate first emission light 400 of the visible light region. According to an example, the light conversion plate 100 may include a refraction plate 110 and first conversion particles 120.

The solar light 300 and the first emission light 400 may be transmitted through a refraction plate 110. For example, the refraction plate 110 may include metal oxide such as titanium oxide (TiO₂), vanadium oxide (V₂O₃), or aluminum oxide (Al₂O₃). Also, the refraction plate 110 may include a polymer such as polymethylmethacrylate (PMMA) or polydimethylsiloxane (PDMS).

The first light conversion particles may be disposed within the refraction plate 110. The first light conversion particles 120 may absorb the solar light 300 to generate the first emission light 400. The first light conversion particles 120 may concentrate the first emission light 400 into the solar cell 200. The first emission light 400 may have a wavelength of the visible light region. The first emission light 400 may be concentrated into the solar cell 200. The first light conversion particles 120 may include luminescent solar concentrators (LSCs).

The solar light of the infrared light region may be transmitted through the solar cell 200. The first light conversion particles 120 may perform an up conversion function. The up conversion may be defined as a process by which light having a long wavelength is converted into light having a short wavelength. According to an embodiment, the first light conversion particles 120 may absorb the solar light 300 of the infrared light region. For example, the first light conversion particles 120 may include phosphors formed of lanthanum-based metal particles. Each of the phosphors may have a diameter of several nanometers.

The solar light 300 of the UV light region may be directly provided into the light conversion plate 100. The first light conversion particles 120 may perform a down conversion function. The down conversion may be defined as a process in which light having a short wavelength is converted into light having a long wavelength. According to an embodiment, the first light conversion particles 120 may absorb the solar light 300 of the UV light region. The first light conversion particles 120 may include quantum dots of cadmium sulfide.

The light conversion plate 100 may have an area greater than that of the solar cell 200. The solar light 300 of the visible light region may transmit the first light conversion particles 120. The first light conversion particles 120 may not reduce transmittance of the refraction plate 110 with respect to the solar light 300 of the visible light region. The refraction plate 110 may be adequately used as the solar window. Thus, the light conversion plate 100 may include the solar window having a large area.

The solar cell 200 may be disposed on the light conversion plate 100. The solar cell 200 may absorb the solar light 300 and the first emission light 400. The solar cell 200 may generate power.

FIG. 2 is a cross-sectional view of the solar cell 200 of FIG. 1.

Referring to FIG. 2, the solar cell 200 may include a lower electrode layer 210, a light absorption layer 220, an upper electrode layer 230, and an upper-optical conversion layer 240.

The lower electrode layer 210 may be disposed on the refraction plate 110. The lower electrode layer 210 may include a transparent electrode. For example, the lower electrode layer 210 may include indium tin oxide (ITO) or indium zinc oxide (IZO).

The light absorption layer 220 may be disposed on the lower electrode layer 210. The light absorption layer 220 may absorb the solar light and the first emission light 400. The light absorption layer 220 may generate power. According to an embodiment, the light absorption layer 220 may absorb the solar light 300 of the visible light region. The light absorption layer 220 may include crystalline silicon. The solar light 300 of the infrared light region may be transmitted through the light absorption layer 220.

The upper electrode layer 230 may be disposed on the light absorption layer 220. The upper electrode layer 230 may include a transparent electrode. For example, the upper electrode layer 230 may include indium tin oxide (ITO) or indium zinc oxide (IZO).

The upper light conversion layer 240 may be disposed on the upper electrode layer 230. The upper light conversion layer 240 may absorb the solar light 300. The upper light conversion layer 240 may perform the up conversion function. The upper light conversion layer 240 may absorb the solar light 300 of the UV light region having a wavelength less than that of the visible light region. According to an example, the upper light conversion layer 240 may include an upper refraction layer 242 and second light conversion particles 244.

The upper refraction layer 242 may be disposed on the upper electrode layer 230. The solar light 300 may be transmitted through the upper refraction layer 242. The upper refraction layer 242 may include metal oxide such as aluminum oxide (Al₂O₃), titanium oxide (TiO₂), or vanadium oxide (V₂O₃). Also, the upper refraction layer 242 may include a silicon compound such as silicon oxide, silicon nitride, or silicon oxynitride.

The second light conversion particles 244 may be disposed within the upper refraction layer 242. The second light conversion particles 244 may absorb a portion of the solar light 300. According to an embodiment, the second light conversion particles 244 may absorb the solar light of the UV light region and transmit the solar light 300 of the visible light region. The second light conversion particles 244 may generate second emission light 500 of the visible region. For example, the second light conversion particles 244 may include quantum dots such as cadmium sulfide (CdS).

The light absorption layer 220 may absorb the second emission light 500. Each of the solar light 300, the first emission light 400, and the second emission light 500 which are absorbed into the light absorption layer 220 may have a wavelength of the visible light region. Thus, the solar cell module according to an embodiment of the present invention may be maximized in light absorption efficiency.

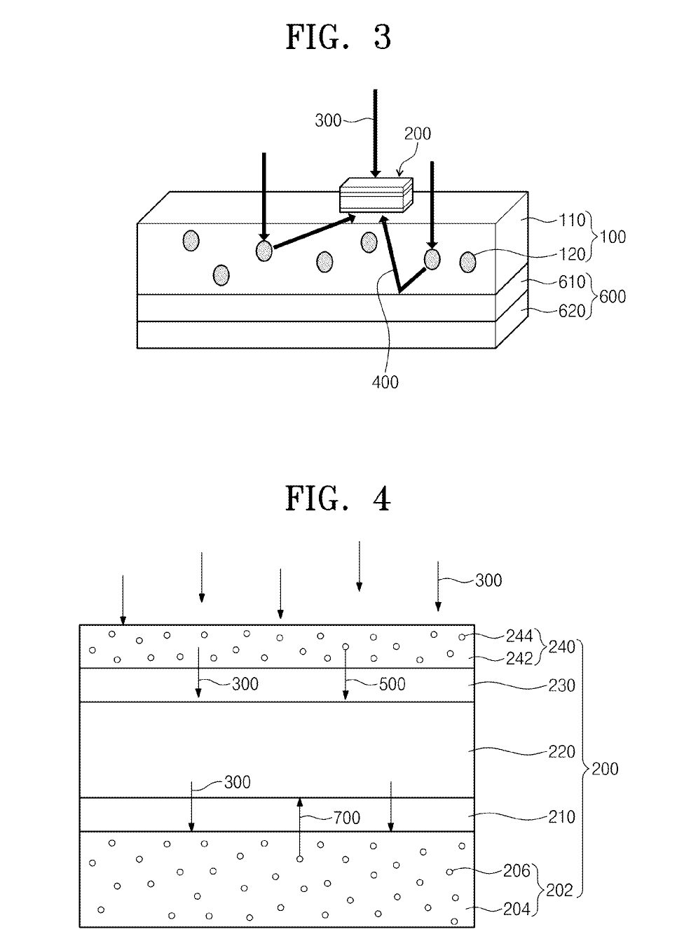

FIG. 3 is a perspective view of a solar cell module according to another embodiment of the present invention.

Referring to FIG. 3, a solar cell module according to another embodiment of the present invention may include refractive index gradient plates 600.

The refractive index gradient plates 600 may be disposed under a light conversion plate 100. The refractive index gradient plates 600 may reflect solar light 300 and first emission light 400 to a solar cell 200. The refractive index gradient plates 600 may act as reflective plates for the solar light 300 and the first emission light 400. According to an example, each of the refractive index gradient plates 600 may have a refractive index less than that of a refraction plate 110. This is done because the solar light 300 and the first emission light 400 are reflected by the refractive index gradient plate 600 having a relatively low refractive index than the refraction plate 110. That is, the solar light 300 and the first emission light 400 may be reflected by top surfaces of the refractive index gradient plates 600. For example, when the refraction plate 100 is provided with titanium oxide, each of the refractive index gradient plates 600 may be provided with aluminum oxide. The titanium oxide may have a refractive index of about 2.2 to about 2.5. The aluminum oxide may have a refractive index of about 1.7.

According to an example, the refractive index gradient plates 600 may include a first refractive index gradient plate 610 and a second refractive index gradient plate 620.

The first refractive index gradient plate 610 may be disposed between the second refractive index gradient plate 620 and the refraction plate 110. The first refractive index gradient plate 610 may have a refractive index less than that of the refraction plate 110. The first refractive index gradient plate 610 may have a refractive index greater than that of the second refractive index gradient plate 620. The solar light 300 and the first emission light 400 may be reflected by a top surface of the first refractive index gradient plate 610.

The second refractive index gradient plate 620 may have a refractive index less than that of the first refractive index gradient plate 610. For example, when the refraction plate 110 and the first refractive index gradient plate 610 are respectively provided with titanium oxide and aluminum oxide, the second refractive index gradient plate 620 may be formed of vanadium oxide. The vanadium oxide may have a refractive index of about 1.58 to about 1.66. The solar light 300 and the first emission light 400 may be reflected by a top surface of the second refractive index gradient plate 620.

In the current embodiment of the present invention, the solar cell module includes the refractive index gradient plates 600 under the light conversion plate 100.

FIG. 4 is a cross-sectional view of a solar cell 200 according to an application example of the present invention.

Referring to FIG. 4, the solar cell 200 according to the application example of the present invention may include a lower light conversion layer 202.

The lower light conversion layer 202 may be disposed under a lower electrode layer 210. The lower light conversion layer 202 may refract and absorb the solar light 300. The solar light 300 of infrared light region may be transmitted trough an upper light conversion layer 240 and a light absorption layer 220. The lower light conversion layer 202 may perform an up conversion function. According to an embodiment, the lower light conversion layer 202 may absorb the solar light 300 of the infrared light region. The lower light conversion layer 202 may generate third emission light 700. For example, the lower light conversion layer 202 may include a lower refraction layer 204 and third light conversion particles 206.

The lower refraction layer 204 may be disposed under the lower electrode layer 210. The lower refraction layer 204 may refract the solar light 300 of the infrared light region. The lower refraction layer 204 may include metal oxide such as aluminum oxide (Al₂O₃), titanium oxide (TiO₂), or vanadium oxide (V₂O₃).

The third light conversion particles 206 may be disposed within the lower refraction layer 204. The third light conversion particles 206 may absorb the solar light 300 of the infrared light region. The third light conversion particles may generate third emission light 700 of a visible light region. The third light conversion particles 206 may include phosphors formed of lanthanum-based metal particles.

Each of the solar light 300, the second emission light 500, and the third emission light 700 which are absorbed into the light absorption layer 220 may have a wavelength of the visible light region. Thus, the solar cell 200 according to the application example of the present invention may be maximized in light absorption efficiency.

In the application example, a lower light conversion layer 202 coupled to the solar cell 200 may be provided. Although the solar cell 200 is not particularly disclosed in the application example, the solar cell 200 described in the current embodiment may include the above-described features. Also, in the application example, the light conversion plate 100 may be substituted with the lower light conversion layer 202.

As described above, the solar cell module of the present invention may include the light conversion plate and the solar cell disposed on the light conversion plate. The light conversion plate may absorb the solar light of the infrared and UV light regions to provide the first emission light of the visible light region to the solar cell. The first emission light may be concentrated into the solar cell. The solar cell may include the lower electrode layer, the light absorption layer, the upper electrode layer, and the upper light conversion layer. The light conversion layer may absorb the solar light of the UV light region to provide the second emission light of the visible light to the light absorption layer. The light absorption layer may absorb the solar light, the first emission light, and the second emission light. Each of the solar light, the first emission light, and the second emission light may have the wavelength of the visible light region. The solar cell module of the present invention may maximize the light absorption efficiency of the solar cell.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A solar cell comprising:
a first light conversion layer;
a lower electrode layer disposed on the first light conversion layer;
a light absorption layer disposed on the lower electrode layer to absorb solar light; and
an upper electrode layer disposed on the light absorption layer,
wherein the first light conversion layer comprises:
a lower refraction layer through which the solar light is transmitted; and
first light conversion particles absorbing refracted light, in which the solar light is refracted by the lower refraction layer, to generate first emission light.

2. The solar cell of claim 1, wherein the first light conversion particles comprise phosphors.

3. The solar cell of claim 2, wherein the phosphors comprise lanthanum-based metal particles.

4. The solar cell of claim 1, wherein the solar cell absorbs the solar light of a visible light region and transmits the solar light of an infrared light region having a wavelength longer than that of the visible light region, and
the first light conversion particles absorb the solar light of the infrared light region to provide the first emission light of the visible light region to the light absorption layer.

5. The solar cell of claim 4, further comprising a second light conversion layer disposed on the upper electrode layer.

6. The solar cell of claim 5, wherein the second light conversion layer comprises:
an upper refraction layer through which the solar light is transmitted; and
second light conversion particles disposed within the upper refraction layer to absorb the solar light of an ultraviolet light region having a wavelength less than that of the visible light region, thereby generating second emission light of the visible light region.

7. The solar cell of claim 6, wherein the second light conversion particles comprise quantum dots.

8. The solar cell of claim 6, wherein the quantum dots comprise cadmium sulfide (CdS).

9. The solar cell of claim 6, wherein each of the lower refraction layer and the upper refraction layer comprises aluminum oxide (Al₂O₃), titanium oxide (TiO₂), or vanadium oxide (V₂O₃).

10. A solar cell module comprising:
a refraction plate;
first light conversion particles disposed within the refraction plate to absorb solar light that is refracted by the refraction plate, thereby generating first emission light; and
a solar cell disposed on the refraction plate to absorb the solar light and the first emission light, thereby generating power.

11. The solar cell module of claim 10, wherein the first light conversion particles comprise luminescent solar concentrators.

12. The solar cell module of claim 11, wherein the luminescent solar concentrators comprise phosphors.

13. The solar cell module of claim 12, wherein the phosphors comprise lanthanum-based metal particles.

14. The solar cell module of claim 10, wherein the refraction plate comprises polymethylmethacrylate (PMMA) or polydimethylsiloxane (PDMS).

15. The solar cell module of claim 10, wherein the first light conversion particles absorb the solar light of an infrared light region.

16. The solar cell module of claim 15, wherein the solar cell comprises:
a lower electrode layer disposed on the light conversion plate;
a light absorption layer disposed on the lower electrode layer;
an upper electrode layer disposed on the light absorption layer; and
a light conversion layer disposed on the upper electrode layer to absorb the solar light, thereby generating second emission light,
wherein light absorption layer transmits the solar light of the infrared light region to absorb the solar light of a visible light region having a wavelength less than that of the infrared light region, the first emission light, and the second emission light.

17. The solar cell module of claim 16, wherein the second light conversion layer comprises:
a refraction layer disposed on the upper electrode layer; and
second light conversion particles disposed within the refraction layer.

18. The solar cell module of claim 16, wherein the second light conversion particles comprise quantum dots.

19. The solar cell module of claim 10, further comprising refractive index gradient plates disposed under the light conversion plate, each refractive index gradient plate having a refractive index less than that of the first light conversion plate.

20. The solar cell module of claim 19, wherein the refractive index gradient plates comprise:
a first refractive index gradient plate disposed under the light conversion plate; and
a second refractive index gradient plate disposed under the first refractive index gradient plate, the second refractive index gradient plate having a refractive index less than that of the first refractive index gradient plate.
